(19) United States
(12) Patent Application Publication
(10) Pub. No.: US 2025/0341571 A1
(43) Pub. Date: Nov. 6, 2025

(54) ELECTRONIC CIRCUIT PROVIDED WITH FUNCTIONAL CIRCUIT HAVING FUNCTION, AND METHOD OF TESTING TIHE ELECTRONIC CIRCUIT

(71) Applicant: NISSHINBO MICRO DEVICES INC., Tokyo (JP)

(72) Inventors: Kagehito Tanji, Ikeda-shi, Osaka (JP); Shiro Matsushita, Ikeda-shi, Osaka (JP)

(21) Appl. No.: 18/861,741

(22) PCT Filed: May 30, 2022
(86) PCT No.: PCT/JP2022/021960

§ 371 Date: Oct. 30, 2024

(51) Int. Cl. G01R 31/3181; G01R 31/319

(52) U.S. Cl. CPC G01R 31/31813; G01R 31/31924

(57) ABSTRACT

An electronic circuit is provided to have a functional circuit and is capable of preventing a mistaken test mode operation from occurring when used in a shopping market. The electronic circuit includes a functional circuit having a prescribed function, and a test circuit for testing the functional circuit for debugging of the functional circuit. The electronic circuit includes: an input circuit for decoding an enable signal for switching the electronic circuit to an operational state, and outputting the decoded enable signal to the functional circuit; a test signal generator for producing a trigger signal for a test signal on the basis of a signal change included in the enable signal; and a computing element for computing a NOR operation of the decoded enable signal and the trigger signal, and outputting the signal from the computing results to the test circuit as a test signal for instructing to execute the test.

### TECHNICAL FIELD

The present invention relates to an electronic circuit including a functional circuit having a predetermined function, and a method of testing the same.

### BACKGROUND ART

It has been already known that an operation in a test mode is mounted as an application of a shipping test or a debugging which is not used by a user in a market.

For example, Patent Document 1 provides an integrated circuit, an electronic circuit board, a DC-DC converter, and a method of testing these circuits, which can achieve downsizing. In the integrated circuit according to the conventional example, when a specific test signal is input to a functional circuit FC, a monitor signal corresponding to the test signal is output from output terminals SW and E (V_{OUT}). When the functional circuit is normal, a value of a monitor signal input to a determiner is a signal expected when the functional circuit is normal, and when the functional circuit is abnormal, the value of the monitor signal is different from the signal at the normal time. Therefore, the functional circuit can be tested by inputting the test signal from the test circuit to the functional circuit. Since the test signal is input to the test circuit via a power supply terminal V_{CC} of the functional circuit, an additional terminal for test is unnecessary, and the apparatus can be downsized.

### PRIOR ART DOCUMENT

### Patent Document

Patent Document 1: Japanese Patent Laid-open Publication No. JP2008-224247A

### SUMMARY OF THE INVENTION

### Problems to be Solved by the Invention

However, in the conventional entry circuit of the test signal, there is such a problem that invalidation is not performed after the test and a re-test cannot be performed, or the entry circuit erroneously enters the test mode in the market by not invalidating the test signal and an unexpected operation is performed.

An object of the present invention is to solve the above problems, and to provide an electronic circuit having a functional circuit that can prevent an operation of a test mode from being erroneously performed when the electronic circuit is used in a market, and a method of testing the same.

### Solutions to the Problems

According to the first aspect of the present invention, there is provided an electronic circuit including a functional circuit having a predetermined function, and a test circuit that tests the functional circuit for debugging of the functional circuit. The electronic circuit includes an input circuit, a test signal generator, and an arithmetic element. The input circuit is configured to decode an enable signal for enabling the electronic circuit in an operating state, and output a decoded enable signal to the functional circuit. The test signal generator is configured to generate a trigger signal for a test signal based on a signal change included in the enable signal. The arithmetic element is configured to execute an operation of a negative OR of the decoded enable signal and the trigger signal, and output a signal of an operation result to the test circuit as a test signal for instructing execution of the test.

According the second aspect of the present invention, there is provided an electronic circuit including a functional circuit having a predetermined function, and a test circuit that tests the functional circuit for debugging of the functional circuit. The electronic circuit includes first and second input circuits, a test signal generator, and an arithmetic element. The first input circuit is configured to decode an enable signal for enabling the electronic circuit in an operating state, and output a decoded enable signal to the functional circuit, and the second input circuit configured to decode a predetermined command signal and output a decoded command signal to the functional circuit. The test signal generator is configured to generate a trigger signal for a test signal based on a signal change included in the command signal, and the arithmetic element is configured to execute an operation of a negative OR of the decoded enable signal and the trigger signal, and output a signal of an operation result to the test circuit as a test signal for instructing execution of the test.

According to a third aspect of the present invention, there is provided an electronic circuit including a functional circuit having a predetermined function, and a test circuit that tests the functional circuit for debugging of the functional circuit. The electronic circuit includes first, second and third input circuits, first and second test generators, and an arithmetic element. The first input circuit is configured to decode an enable signal enabling the electronic circuit in an operating state, and output a decoded enable signal to the functional circuit, and the second input circuit is configured to decode a predetermined first command signal, and output the first decoded command signal to the functional circuit. The first test signal generator is configured to generate a first trigger signal for a test signal based on a signal change included in the first command signal, the third input circuit is configured to decode a predetermined second command signal, and output the second decoded command signal to the functional circuit, and the second test signal generator is configured to generate a second trigger signal for a test signal based on a signal change included in the second command signal. The arithmetic element is configured to execute an operation of a negative OR of the decoded enable signal, the first trigger signal, and the second trigger signal, and output a signal of an operation result to the test circuit as a test signal for instructing execution of the test.

### Effects of the Invention

Therefore, according to the electronic circuit and the like of the present invention, there is provided the arithmetic element that performs an operation of a negative OR of the decoded enable signal or the encoding command signal and the trigger signal, and outputs a signal of an operation result to the test circuit as a test signal for instructing execution of the test. Therefore, it is possible to prevent the electronic circuit having the functional circuit from erroneously entering the operation of the test mode when used in the market.

### BRIEF DESCRIPTION OF THE DRAWINGS

FIG. 1 is a block diagram illustrating a configuration example of an electronic circuit 1 according to a first embodiment.

FIG. 2 is a timing chart of each voltage illustrating the operation of the electronic circuit 1 in FIG. 1.

FIG. 3 is a circuit diagram illustrating a configuration example of a test signal generator 13A according to a first modified embodiment.

FIG. 4 is a timing chart of each voltage illustrating an operation of the test signal generator 13A in FIG. 3.

FIG. 5 is a circuit diagram illustrating a configuration example of a test signal generator 13B according to a second modified embodiment.

FIG. 6 is a timing chart of each voltage illustrating an operation of the test signal generator 13B in FIG. 5.

FIG. 7 is a circuit diagram illustrating a configuration example of a test signal generator 13C according to a third modified embodiment.

FIG. 8 is a circuit diagram illustrating a configuration example of a test signal generator 13D according to a fourth modified embodiment.

FIG. 9 is a block diagram illustrating a configuration example of an electronic circuit 1A according to a second embodiment.

FIG. 10 is a timing chart of each voltage illustrating the operation of the electronic circuit 1A in FIG. 9.

FIG. 11 is a block diagram illustrating a configuration example of an electronic circuit 1B according to a third embodiment.

FIG. 12 is a block diagram illustrating a configuration example of an electronic circuit 1C according to a fourth embodiment.

FIG. 13 is a block diagram illustrating a configuration of an electronic circuit 101 according to a comparative example.

FIG. 14 is a circuit diagram illustrating a configuration of a test signal generator 13 in FIG. 13.

FIG. 15 is a timing chart of each voltage illustrating the operation of the test signal generator 13 in FIG. 14.

FIG. 16 is a timing chart of each voltage when noise is superimposed on a ground line in the test signal generator 13 in FIG. 14.

FIG. 17 is a timing chart of each voltage when noise is superimposed on a connection line of a terminal T2 in a test signal generator 13 in FIG. 14.

### DETAILED DESCRIPTION

Hereinafter, embodiments and modified embodiments according to the present invention will be described with reference to the drawings. It is noted that the same or similar components are denoted by the same reference numerals.

### Findings of Inventors

Patent Document 1 discloses a configuration in which a test can be performed without adding a test dedicated terminal for the purpose of test, but such a problem that any re-test cannot be performed due to invalidation after the test cannot be solved. That is, in the state of the “chip enable signal EN=H level” in which the functional circuit operates, the state does not transition even when the entry condition of the test mode is satisfied, and thus, it is possible to avoid a malfunction in actual use without invalidating the test function after the test.

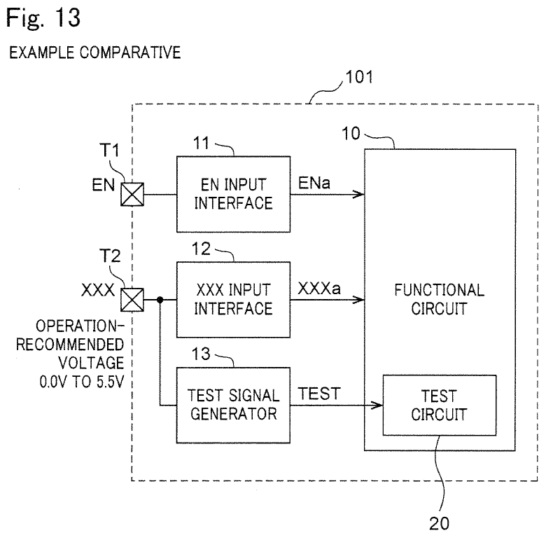

FIG. 13 is a block diagram illustrating a configuration of an electronic circuit 101 according to a comparative example.

Referring to FIG. 13, the electronic circuit 101 includes terminals T1 and T2, input interfaces 11 and 12, a test signal generator 13, and a functional circuit 10 that executes a predetermined function and incorporates a test circuit 20. The input interface 11 decodes a chip enable signal EN input to the terminal T1 into a chip enable signal ENa that is a predetermined rising edge signal, and then outputs the chip enable signal EN to the functional circuit 10. In addition, the input interface 12 decodes a command signal XXX input to the terminal T2 into a command signal XXXa that is a predetermined rising edge signal, and then outputs the command signal XXXa to the functional circuit 10. Further, the test signal generator 13 outputs a H-level test signal TEST to the functional circuit 10 when the command signal XXX input to the terminal T2 becomes a signal condition of a predetermined test mode. Then, in response to the H-level test signal TEST, the test circuit 20 built in the functional circuit 10 executes predetermined test for debugging on the functional circuit 10.

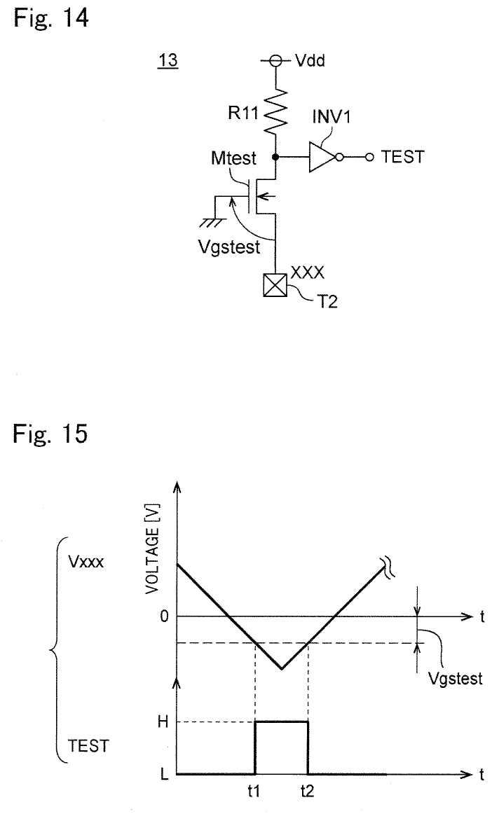

FIG. 14 is a circuit diagram illustrating a configuration of the test signal generator 13 in FIG. 13. In addition, FIG. 15 is a timing chart of each voltage illustrating the operation of the test signal generator 13 in FIG. 14. In FIG. 15 and other figures, Vxxx represents the voltage of the command signal XXX.

Referring to FIG. 14, the test signal generator 13 includes an N-channel MOS transistor Mtest, a resistor R11, and an inverter INV1. In this case, a power supply voltage Vdd is connected to the terminal T2 via the resistor R11 and the drain and source of the MOS transistor Mtest. The gate of the MOS transistor Mtest is grounded, and the MOS transistor Mtest is in an off state. The signal from the drain of the MOS transistor Mtest is inverted by the inverter INV1 and then output as a test signal TEST.

In the test signal generator 13 configured as described above, as illustrated in FIG. 15, when the voltage of the terminal T2 becomes equal to or lower than a voltage Vgstest that is a threshold voltage of a MOS transistor Mtest, the test signal TEST becomes the H level.

That is, in the circuits in FIGS. 13 and 14, in order to make the functional circuit 10 enter the test mode without adding any dedicated terminal, a condition other than the operation recommended condition of the terminal used for controlling the integrated circuit is set as the entry condition.

However, when the electronic circuit 101 is used in the switching regulator, not only the output voltage but also the power supply voltage and the ground voltage may change due to switching noise or the like, and the entry condition may be satisfied. In addition, noise may also be mixed in the voltage of the command signal XXX of the terminal T2 which is an external input.

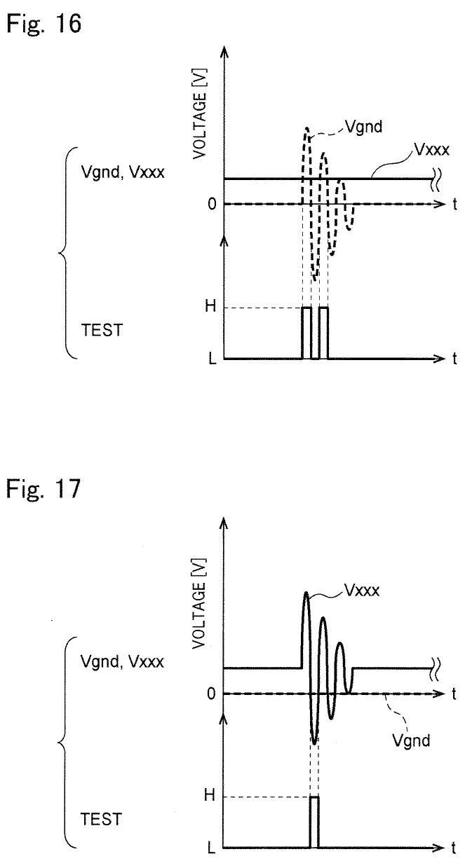

FIG. 16 is a timing chart of each voltage when noise is superimposed on the ground line in the test signal generator 13 in FIG. 14. In FIG. 16 and other figures, Vgnd represents the ground voltage. As is apparent from FIG. 16, there is a case where the ground voltage changes and the test signal TEST erroneously becomes the H level.

FIG. 17 is a timing chart of each voltage when noise is superimposed on the connection line of the terminal T2 in the test signal generator 13 in FIG. 14. As is apparent from FIG. 17, there is a case where the voltage of the command signal XXX changes and the test signal TEST becomes the H level.

Since the entry state of the test mode is normally latched, when the test signal TEST reaches the H level even once as illustrated in FIG. 16 or 17, there is such a problem that the test signal TEST cannot be returned unless the functional circuit 10 of the electronic circuit 101 is restarted.

The present inventors have devised the following embodiments and modified embodiments in order to solve the above problems. The embodiment according to the present invention has the following features when mounted in a test mode for use in a shipment test or for use in debugging. It is a feature that “in the “chip enable signal EN=H level” state in which the functional circuit 10 operates, the state of the test signal TEST does not transition from the L level to the H level even when the entry condition of the test mode is satisfied”.

### First Embodiment

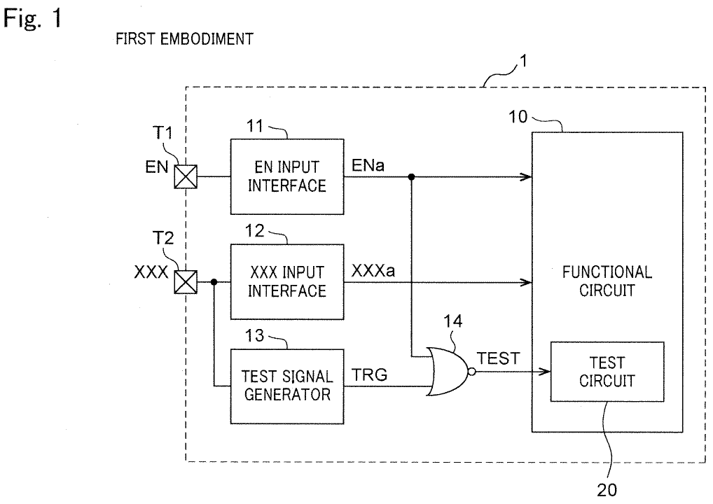

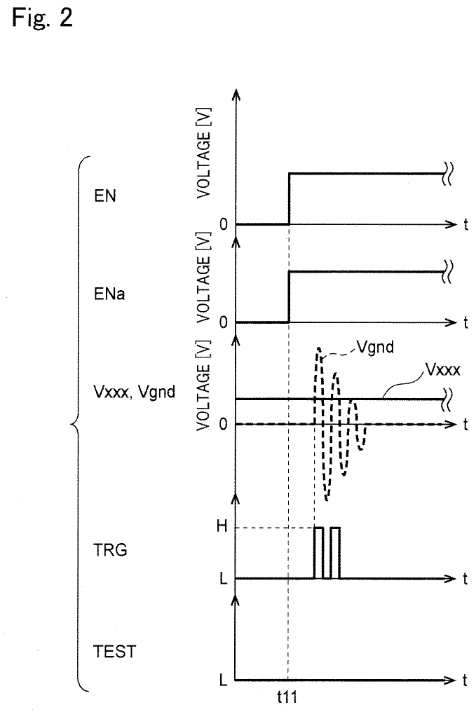

FIG. 1 is a block diagram illustrating a configuration example of an electronic circuit 1 according to a first embodiment. In addition, FIG. 2 is a timing chart of each voltage illustrating the operation of the electronic circuit 1. In this case, the test signal generator 13 in FIG. 1 has, for example, the circuit configuration in FIG. 14. The electronic circuit 1 in FIG. 1 is different from the electronic circuit 101 in FIG. 13 in the following points.
(1) The test signal from the test signal generator 13 is set as a trigger signal TRG.
(2) A NOR gate 14, which is an arithmetic element that performs an operation of the negative OR of the enable signal ENa and the trigger signal TRG, and outputs the signal of the operation result as a test signal TEST to the functional circuit 10, is further included.

The other configurations are similar to those of the electronic circuit 101 in FIG. 13, and as illustrated in FIGS. 14 and 15, in the test signal generator 13, the test signal TEST becomes the H level when the voltage of the terminal T2 becomes equal to or lower than the voltage Vgstest which is the threshold voltage of the MOS transistor Mtest. Then, in response to the H-level test signal TEST, the test circuit 20 built in the functional circuit 10 executes predetermined test for debugging use on the functional circuit 10.

The test mode is not invalidated even after the shipment test. In addition, each of the input interfaces 11 and 12 are an example of an input circuit that decodes an input signal, and outputs an encoded signal.

In the electronic circuit 1 configured as described above, when the enable signal ENa has the H level, the NOR gate 14 prevents the H level test signal TEST from being output even if the test signal generator 13 outputs the H-level trigger signal TRG. That is, as illustrated in FIG. 2, even if noise is superimposed on the ground voltage or the H-level trigger signal TRG is output, if the enable signal ENa has the H level, the H-level test signal TEST is not output.

As described above, according to the first embodiment, in the “chip enable signal EN=H level” state in which the functional circuit 10 operates, even when the entry condition of the test mode is satisfied, it is possible to prevent the state transition of the test signal TEST from the L level to the H level, that is, the occurrence of the test signal TEST having the H level. Therefore, in the electronic circuit 1 having the functional circuit, it is possible to prevent the electronic circuit 1 from erroneously entering the test mode when used in the market.

It is noted that the functional circuit 10 in FIG. 1 and subsequent figures is, for example, a linear regulator, a switching regulator, a reference voltage generation circuit, a protection circuit such as an electronic circuit, a memory circuit, a digital processing circuit, or the like.

### First Modified Embodiment

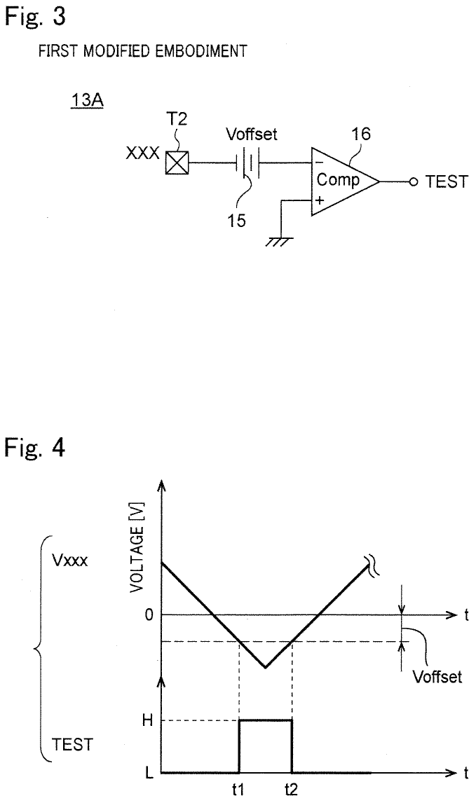

FIG. 3 is a circuit diagram illustrating a configuration example of a test signal generator 13A according to a first modified embodiment. In addition, FIG. 4 is a timing chart of each voltage illustrating an operation of the test signal generator 13A in FIG. 3.

Referring to FIG. 3, the test signal generator 13A includes an offset DC voltage source 15 that applies a predetermined offset voltage to the command signal, and a comparator 16. The command signal XXX input to the terminal T2 is offset in the positive voltage direction in terms of direct current by the DC voltage source 15, and then, is input to the inverting input terminal of the comparator 16. The non-inverting input terminal of the comparator 16 is grounded. The comparator 16 outputs the H-level test signal TEST (signal change included in the command signal XXX) when the voltage of the inverting input terminal becomes equal to or lower than the voltage of the non-inverting input terminal. That is, as illustrated in FIG. 4, when the voltage Vxxx of the command signal XXX becomes equal to or less than −Voffset, the H-level test signal TEST is output.

According to the first modified embodiment configured as described above, in a manner similar to that of the first embodiment, in the “chip enable signal EN=H level” state in which the functional circuit 10 operates, even if the entry condition of the test mode is satisfied, it is possible to prevent the state transition of the test signal TEST from the L level to the H level, that is, the occurrence of the H-level test signal TEST. Therefore, in the electronic circuit 1 having the functional circuit, it is possible to prevent the electronic circuit 1 from erroneously entering the test mode when used in the market.

### Second Modified Embodiment

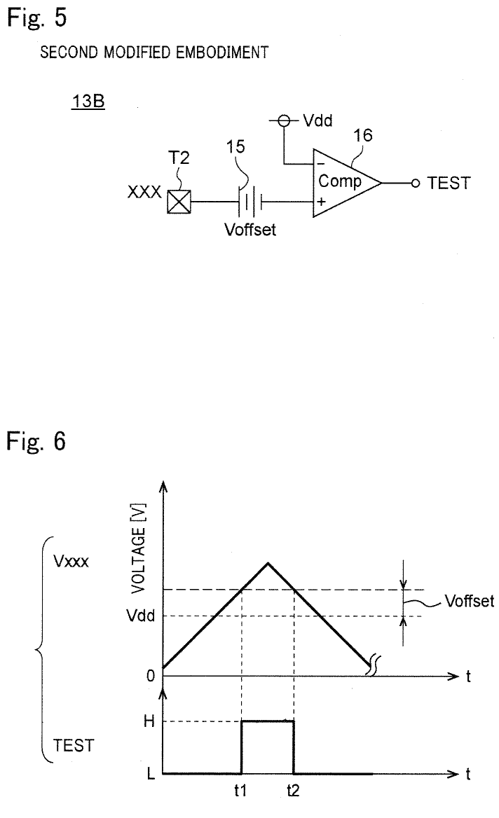

FIG. 5 is a circuit diagram illustrating a configuration example of a test signal generator 13B according to a second modified embodiment. In addition, FIG. 6 is a timing chart of each voltage illustrating an operation of the test signal generator 13B in FIG. 5.

Referring to FIG. 5, the test signal generator 13B includes the offset DC voltage source 15 that applies a predetermined offset voltage to the command signal, and the comparator 16. The command signal XXX input to the terminal T2 is offset in the negative voltage direction in terms of direct current by the DC voltage source 15, and then input to the non-inverting input terminal of the comparator 16. The inverting input terminal of the comparator 16 is connected to the power supply voltage Vdd. The comparator 16 outputs the H-level test signal TEST when the voltage of the non-inverting input terminal becomes equal to or higher than the voltage of the inverting input terminal. That is, as illustrated in FIG. 6, when the voltage Vxxx of the command signal XXX becomes equal to or higher than (Vdd+Voffset), the H-level test signal TEST is output.

According to the second modified embodiment configured as described above, in a manner similar to those of the first embodiment and the first modified embodiment, in the “chip enable signal EN=H level” state in which the functional circuit 10 operates, even if the entry condition of the test mode is satisfied, it is possible to prevent the state transition of the test signal TEST from the L level to the H level, that is, the occurrence of the H-level test signal TEST. Therefore, in the electronic circuit 1 having the functional circuit, it is possible to prevent the electronic circuit 1 from erroneously entering the test mode when used in the market.

### Third Modified Embodiment

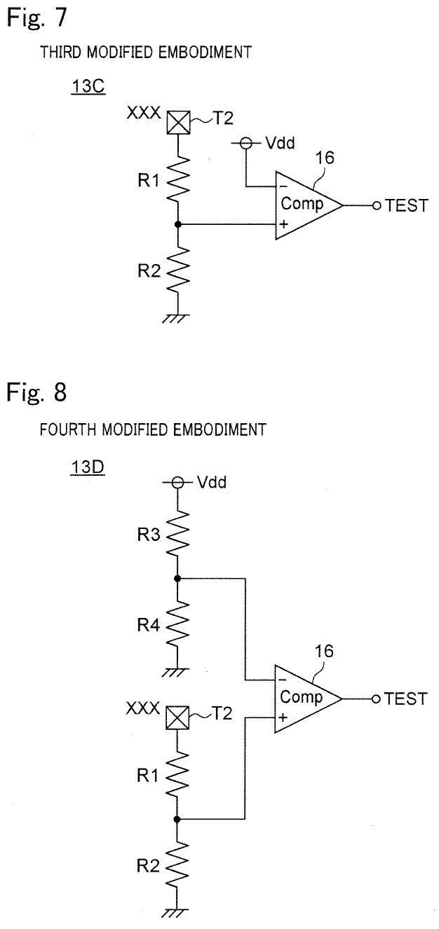

FIG. 7 is a circuit diagram illustrating a configuration example of a test signal generator 13C according to a third modified embodiment. In FIG. 7, the test signal generator 13C is different from the test signal generator 13B in FIG. 5 in the following points.
(1) Instead of the offset DC voltage source 15, voltage-dividing resistors R1 and R2 connected in series with each other and inserted between the terminal T2 and the ground are provided.

Referring to FIG. 7, the voltage of the command signal XXX input to the terminal T2 is divided by the voltage-dividing resistors R1 and R2, and the divided voltage is input to the non-inverting input terminal of the comparator 16. The test signal generator 13C configured as described above operates in a manner similar to that of the second modified embodiment in FIG. 5, and has the similar action and effect to those of the second modified embodiment in FIG. 5.

### Fourth Modified Embodiment

FIG. 8 is a circuit diagram illustrating a configuration example of a test signal generator 13D according to a fourth modified embodiment. In FIG. 8, the test signal generator 13D is different from the test signal generator 13C in FIG. 7 in the following points.
(1) To the inverting input terminal of the comparator 16, the power supply voltage Vdd is divided by voltage-dividing resistors R3 and R4 connected in series with each other, and the divided voltage is input to the inverting input terminal of the comparator 16.

Referring to FIG. 8, the test signal generator 13D configured as described above operates in a manner similar to that of the third modified embodiment in FIG. 7 except that the comparison reference voltage of the comparator 16 becomes a predetermined voltage lower than the power supply voltage Vdd, and has the similar action and effect to those thereof.

### Second Embodiment

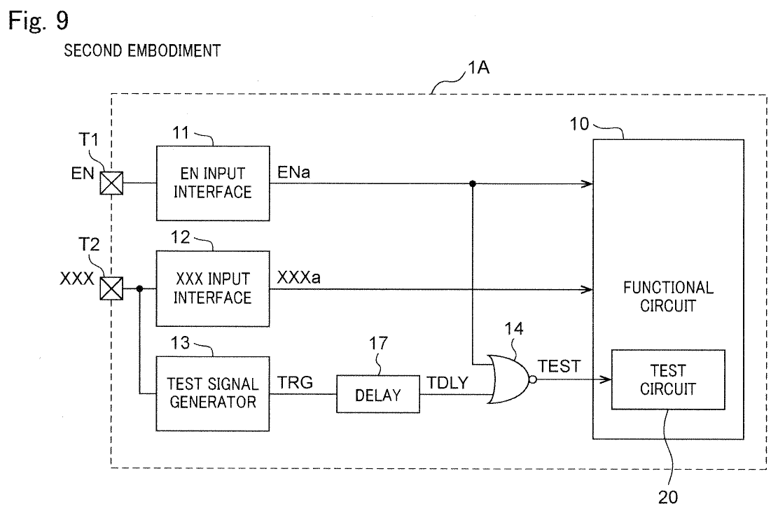

FIG. 9 is a block diagram illustrating a configuration example of an electronic circuit 1A according to a second embodiment. The electronic circuit 1A in FIG. 9 is different from the electronic circuit 1 in FIG. 1 in the following points.
(1) A delay circuit 17 that delays the input signal by a predetermined delay time Td is inserted between the output terminal of the test signal generator 13 and the input terminal of a NOR gate 14. In this case, the delay time Td corresponds to the signal processing time of an input interface 11.

Differences will be described below.

Referring to FIG. 9, the delay circuit 17 delays a trigger signal TRG from the test signal generator 13 by the predetermined delay time Td, and then outputs a delay signal TDLY to the NOR gate 14.

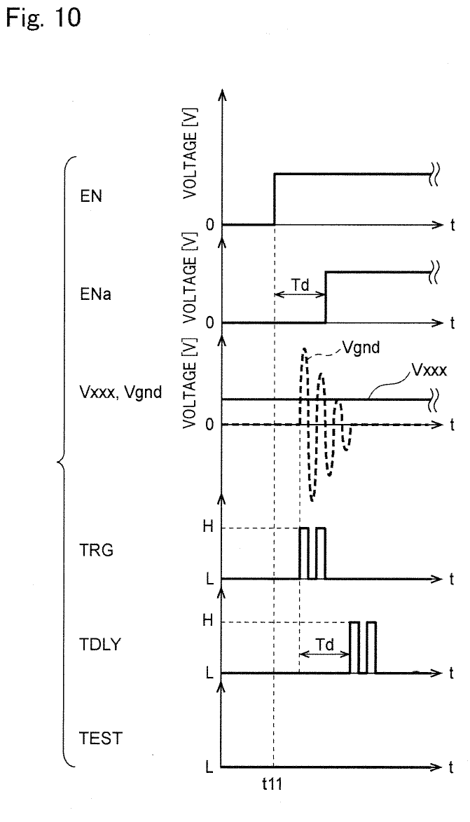

FIG. 10 is a timing chart of each voltage illustrating the operation of the electronic circuit 1A in FIG. 9. As is apparent from FIG. 10, the circuit that fixes a test signal TEST to the L level when the enable signal ENa has the H level has a unique function and effect that the timing of the delay signal TDLY can be adjusted in consideration of the signal processing time of the input interface 11 and the like. The other functions and effects are the same as those of the first embodiment.

When the signal processing time of the input interface 11 is not considered, the delay circuit 17 may be deleted.

### Third Embodiment

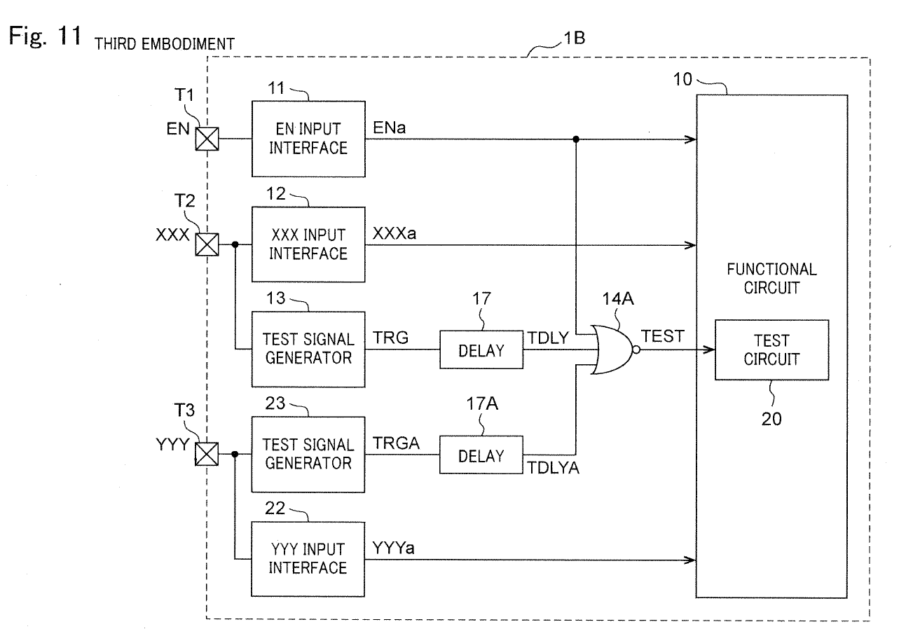

FIG. 11 is a block diagram illustrating a configuration example of an electronic circuit 1B according to a third embodiment. The electronic circuit 1B in FIG. 11 is different from the electronic circuit 1A in FIG. 9 in the following points.
(1) A terminal T3 that receives another command signal YYY is further provided.
(2) An input interface 22 and a test signal generator 23 connected to the terminal T3 are further provided.
(3) Instead of the NOR gate 14, a NOR gate 14A having three input terminals is provided.
(4) A delay circuit 17A having the same configuration as the delay circuit 17 is inserted between the test signal generator 23 and the NOR gate 14A.

Differences will be described below.

Referring to FIG. 11, the input interface 22 decodes a command signal YYY input to the terminal T3 into a command signal YYYa that is a predetermined rising edge signal, and then outputs the command signal YYYa to the functional circuit 10. In addition, the test signal generator 23 outputs a H-level trigger signal TRGA to the functional circuit 10 as a delay signal TDLYA via the delay circuit 17A when the command signal YYY input to the terminal T3 becomes a signal condition of a predetermined test mode.

According to the third embodiment configured as described above, in response to the two command signals XXX and YYY, the test signal TEST can be generated in consideration of the signal processing time of the input interface 11. The other functions and effects are the same as those of the second embodiment.

When the signal processing time of the input interface 11 is not considered, the delay circuits 17 and 17A may be deleted. In addition, in the fourth embodiment, the test signal TEST is generated using the two trigger signals TRG and TRGA, but the present invention is not limited thereto, and for example, the test signal TEST may be generated using three or more trigger signals.

### Fourth Embodiment

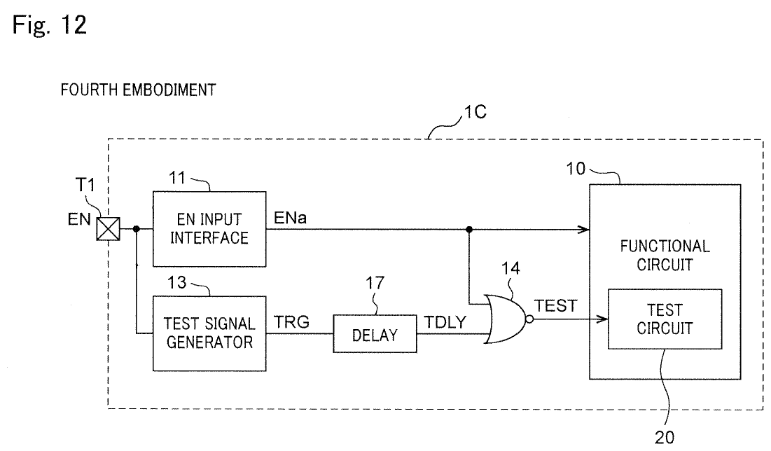

FIG. 12 is a block diagram illustrating a configuration example of an electronic circuit 1C according to a fourth embodiment. The electronic circuit 1C in FIG. 12 is different from the electronic circuit 1 in FIG. 1 in the following points.
(1) The terminal T2 and the input interface 12 are deleted.
(2) The test signal generator 13 generates the trigger signal TRG under the predetermined signal condition (first embodiment, first modified embodiment, second modified embodiment, and the like) in a manner similar to that of the command signal XXX based on the enable signal EN input to the terminal T1, and outputs the trigger signal TRG to the NOR gate 14 as a delay signal TDLY via the delay circuit 17.

According to the fourth embodiment configured as described above, the trigger signal TRG is generated based on the enable signal EN under a predetermined signal condition in a manner similar to that of the command signal XXX, so that the trigger signal TRG and the test signal TEST can be generated by using the enable signal EN also as the entry condition of the command signal XXX without providing the command signal XXX and a terminal T2. The fourth embodiment has the similar action and effect to those of the first embodiment except for this.

It is noted that, in FIG. 12, when the signal processing time of an input interface 11 is not considered, the delay circuit 17 may not be provided. In addition, the test signal generators 13 and 23 may include the above-described test signal generators 13A to 13D.

### INDUSTRIAL APPLICABILITY

As described above in detail, according to the electronic circuit and the like of the present invention, it is possible to prevent an electronic circuit having a functional circuit from erroneously entering the test mode when used by a user in the market.

### EXPLANATION OF REFERENCES

1, 1A to 1C, and 101 Electronic circuit
10 Functional circuit
11, 12, and 22 Input interface
13, 13A to 13D, and 23 Test signal generator
14, and 14A NOR gate
15 DC voltage source
16 Comparator
17, and 17A Delay circuit
20 Test circuit
INV1 Inverter
Mtest MOS transistor
R1 to R11 Resistor
T1 to T3 Terminal

1. An electronic circuit comprising a functional circuit having a predetermined function, and a test circuit that tests the functional circuit for debugging of the functional circuit, the electronic circuit comprising:
an input circuit configured to decode an enable signal for enabling the electronic circuit in an operating state, and output a decoded enable signal to the functional circuit;
a test signal generator configured to generate a trigger signal for a test signal based on a signal change included in the enable signal; and
an arithmetic element configured to execute an operation of a negative OR of the decoded enable signal and the trigger signal, and output a signal of an operation result to the test circuit as a test signal for instructing execution of the test.

2. The electronic circuit as claimed in claim 1, further comprising a delay circuit inserted between the test signal generator and the arithmetic element, the delay circuit configured to delay the trigger signal by a processing time of the input circuit, and output the delayed trigger signal to the arithmetic element.

3. An electronic circuit comprising a functional circuit having a predetermined function, and a test circuit that tests the functional circuit for debugging of the functional circuit, the electronic circuit comprising:
a first input circuit configured to decode an enable signal for enabling the electronic circuit in an operating state, and output a decoded enable signal to the functional circuit;
a second input circuit configured to decode a predetermined command signal and output a decoded command signal to the functional circuit;
a test signal generator configured to generate a trigger signal for a test signal based on a signal change included in the command signal; and
an arithmetic element configured to execute an operation of a negative OR of the decoded enable signal and the trigger signal, and output a signal of an operation result to the test circuit as a test signal for instructing execution of the test.

4. The electronic circuit as claimed in claim 3, further comprising a delay circuit inserted between the test signal generator and the arithmetic element, the delay circuit configured to delay the trigger signal by a processing time of the first input circuit, and output the delayed trigger signal to the arithmetic element.

5. An electronic circuit comprising a functional circuit having a predetermined function, and a test circuit that tests the functional circuit for debugging of the functional circuit, the electronic circuit comprising:
a first input circuit configured to decode an enable signal enabling the electronic circuit in an operating state, and output a decoded enable signal to the functional circuit;
a second input circuit configured to decode a predetermined first command signal, and output the first decoded command signal to the functional circuit;
a first test signal generator configured to generate a first trigger signal for a test signal based on a signal change included in the first command signal;
a third input circuit configured to decode a predetermined second command signal, and output the second decoded command signal to the functional circuit;
a second test signal generator configured to generate a second trigger signal for a test signal based on a signal change included in the second command signal; and
an arithmetic element configured to execute an operation of a negative OR of the decoded enable signal, the first trigger signal, and the second trigger signal, and output a signal of an operation result to the test circuit as a test signal for instructing execution of the test.

6. The electronic circuit as claimed in claim 5, further comprising:
a first delay circuit inserted between the first test signal generator and the arithmetic element, the first delay circuit configured to delay the first trigger signal by a processing time of the first input circuit, and output a delayed first trigger signal to the arithmetic element; and
a second delay circuit inserted between the second test signal generator and the arithmetic element, the second delay circuit configured to delay the second trigger signal by a processing time of the first input circuit, and output a delayed second trigger signal to the arithmetic element.

7. The electronic circuit as claimed in claim 3,
wherein the test signal generator comprises:
a series circuit including a resistor and a gate-grounded MOS transistor which are connected in series, the series circuit being connected between a predetermined power supply voltage and an input terminal of the command signal; and
an inverter configured to invert a signal from an output terminal of the MOS transistor, and output the inverted signal as the trigger signal.

8. The electronic circuit as claimed in claim 3, wherein
the test signal generator comprises:
a DC voltage source configured to apply a predetermined offset voltage to a signal which is input to an input terminal of the command signal; and
a comparator configured to compare the signal to which the offset voltage is applied with a power supply voltage or a ground voltage, and output a comparison result signal as the trigger signal.

9. The electronic circuit as claimed in claim 3, wherein
the test signal generator comprises:
a voltage-dividing resistor configured to divide a voltage of a signal which is input to an input terminal of the command signal, and output a divided voltage; and
a comparator configured to compare the divided voltage with a power supply voltage, and output a comparison result signal as the trigger signal.

10. The electronic circuit as claimed in claim 3, wherein
the test signal generator comprises:
a first voltage-dividing resistor configured to divide a voltage of a power supply voltage, and outputs a first divided voltage;
a second voltage-dividing resistor configured to divide a voltage of a signal input to an input terminal of the command signal, and output a second divided voltage; and
a comparator configured to compare the first divided voltage with the second divided voltage, and output a comparison result signal as the trigger signal.

11. A method of testing an electronic circuit, the electronic circuit comprising a functional circuit having a predetermined function, and a test circuit that tests the functional circuit for debugging of the functional circuit, the method comprising the steps of:
decoding, by an input circuit, an enable signal for enabling the electronic circuit in an operating state, and outputting a decoded enable signal to the functional circuit;
generating, by a test signal generator, a trigger signal for a test signal based on a signal change included in the enable signal; and
performing, by an arithmetic element, an operation of a negative OR of the decoded enable signal and the trigger signal, and outputting a signal of an operation result to the test circuit as a test signal for instructing execution of the test.

12. A method of testing an electronic circuit, the electronic circuit comprising a functional circuit having a predetermined function, and a test circuit that tests the functional circuit for debugging of the functional circuit, the method comprising the steps of:
decoding, by a first input circuit, an enable signal for enabling the electronic circuit in an operating state, and outputting the decoded enable signal to the functional circuit;
decoding, by a second input circuit, a predetermined command signal and outputting the decoded command signal to the functional circuit;
generating, by a test signal generator, a trigger signal for a test signal based on a signal change included in the command signal; and
performing, by an arithmetic element, an operation of a negative OR of the decoded enable signal and the trigger signal, and outputting a signal of an operation result to the test circuit as a test signal for instructing execution of the test.

13. A method of testing an electronic circuit, the electronic circuit comprising a functional circuit having a predetermined function, and a test circuit that tests the functional circuit for debugging of the functional circuit, the method comprising the steps of:
decoding, by a first input circuit, an enable signal for enabling the electronic circuit in an operating state, and outputting the decoded enable signal to the functional circuit;
decoding, by a second input circuit, a predetermined first command signal, and outputting the first decoded command signal to the functional circuit;
generating, by a first test signal generator, a first trigger signal for a test signal based on a signal change included in the first command signal;
decoding, by a third input circuit, a predetermined second command signal, and outputting the second decoded command signal to the functional circuit;
generating, by a second test signal generator, a second trigger signal for a test signal based on a signal change included in the second command signal; and
performing, by an arithmetic element, an operation of a negative OR of the decoded enable signal, the first trigger signal, and the second trigger signal, and outputting a signal of an operation result to the test circuit as a test signal for instructing execution of the test.
